(19) United States
(12) Patent Application Publication
(10) Pub. No.: US 2010/0065120 A1
(43) Pub. Date: Mar. 18, 2010

(54) Encapsulant with Modified Refractive Index

(75) Inventor: Mark McDonald, Milpitas, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/209,675

(22) Filed: Sep. 12, 2008

(51) Int. Cl. H01L 31/00; B05D 5/12

(52) U.S. Cl. 136/259; 427/74

(57) ABSTRACT

The present invention provides an encapsulant material with a modified index of refraction for increasing the acceptance angle of a concentrated photovoltaic system. The encapsulant material may include filler material of a higher index of refraction than the encapsulant. The filler material may be particulates that are smaller than the wavelength of light converted to electricity by a solar cell.

### BACKGROUND OF THE INVENTION

A concentrating photovoltaic (CPV) is a solar energy device which utilizes one or more optical elements to concentrate incoming light onto a solar cell. This concentrated light, which may exhibit a power per unit area of 500 or more suns, requires an optical system that can withstand such intensity over an operational lifetime and efficiently deliver this light to a solar cell. The optical elements in a concentrated solar energy device are integral components of the device and require optimization in order to utilize the maximum amount of available solar radiation. In some CPV systems, an optical component such as a non-imaging concentrator may be utilized to assist in transmitting concentrated light to the solar cell. Often an encapsulant material is used to reduce transmission losses that can occur at the interface between the non-imaging concentrator, or other optical component, and solar cell.

Limitations of available materials having the necessary optical properties and durability to withstand the intense conditions of a CPV may constrain the overall performance that can be achieved by a system. In particular, a mismatch of refractive indices between materials, such as a non-imaging concentrator and solar cell, can result in undesirable optical losses. Thus, there exists a need for an improved optical system for use in a solar concentrator in order to minimize differences in refractive index of the light path to a solar cell. Such a system may improve the acceptance angle of rays entering the system and thereby enable greater electrical energy to be produced from a CPV system.

### SUMMARY OF THE INVENTION

The present invention is directed to a concentrated photovoltaic (CPV) system in which the refractive index of an encapsulant material is modified to approach or substantially match that of an optical element to which it is coupled. The encapsulant may also be coupled to a solar cell that converts solar radiation into usable electrical energy. In one embodiment the encapsulant may be silicone combined with a filler material. The filler material may have a higher index of refraction than silicone, for example titania particles, resulting in a composite encapsulant, or “effective medium,” with higher index of refraction than silicone alone. In one aspect, the particle size of the filler material may be smaller than the least wavelength of light converted into energy by the solar cell (e.g., 200 nm diameter particles). In another aspect, the amount of filler may be adjusted, such as to approximately 20% of the encapsulant volume, to achieve the desired composite refractive index.

The invention also provides a method for increasing the acceptance angle of a CPV system which includes applying an encapsulant with a refractive index that closely matches that of an optical element, such as a non-imaging concentrator, and coupling that to a solar cell. The encapsulant may be prepared by mixing the encapsulant with a filler material of a different refractive index. The refractive index of the filler/encapsulant system may then be altered—typically raised—to approximate the refractive index of the non-imaging concentrator. In one embodiment, the encapsulant may be combined with titania (e.g., TiO₂) spheres, and the spheres may be smaller than the wavelength of light that is converted by the solar cell.

### BRIEF DESCRIPTION OF THE FIGURES

FIG. 1 shows a schematic view of a current optical system for a CPV showing an optical device and an encapsulant with unmatched refractive indices.

FIG. 2 shows a schematic view of an ideal optical system having matched refractive indices.

FIG. 3 shows a schematic view of an embodiment of the present invention, showing an optical system incorporating an encapsulant with filler particles.

FIG. 4 shows a graph of the calculated percent transmission at the interface of an optical element and an encapsulant for a variety of optical systems.

### DETAILED DESCRIPTION

The present invention provides an optical system in which an encapsulant is modified to have a refractive index that approaches or substantially matches that of an optical component to which it is coupled. The present invention may be used in conjunction with a CPV system in order to increase the acceptance angle of light reaching the solar cell. Thus a CPV system of this invention may provide usable electrical energy from solar radiation collected at broader range of angles than a CPV system with a narrower range of acceptance angles. This may result in increased performance of the CPV system, as more light is converted into usable electrical energy. In one embodiment a filler material may be used to modify the index of refraction of the encapsulant.

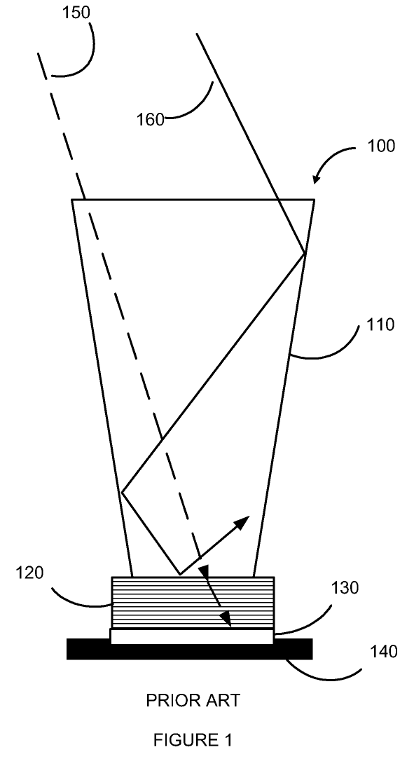

FIG. 1 is a schematic diagram of an exemplary optical system 100 used in the art to provide electrical energy from solar radiation. In optical system 100, an encapsulant 120 serves as an interface between an optical element (e.g., non-imaging concentrator) 110 and a solar cell 130, which is generally assembled in a leadframe package 140. Solar cell 130 may comprise a III-V solar cell, a II-VI solar cell, a silicon solar cell, or any other type of solar cell that is or becomes known. Solar cell 130 may comprise any number of active, dielectric and metallization layers, and may be fabricated using any suitable methods that are or become known.

In FIG. 1, an optical device in the form of an optical element 110, which may be, for example, a lightguide or a truncated prism, is shown. Note that while a truncated prism is depicted in this disclosure, other optical elements such as a refractive element or Fresnel lens may be substituted for optical element 110 while still remaining within the scope of this invention. Optical element 110 enables incoming solar radiation to be delivered to solar cell 130 from a range of incident angles represented by rays 150 and 160. Materials for encapsulant 120 which are deemed suitable for CPV applications are typically limited to silicones having a narrow range of refractive indices near 1.4. Optical element 110 typically requires glass, such as BK7 with a refractive index of 1.52, to meet the desired design parameters such as UV shielding and cost. Because of this transition from a higher refraction index material (e.g., BK7 glass) to a lower index material (e.g., silicone) at the interface between optical element 110 and encapsulant 120, a total internal reflection (TIR) condition may occur for a portion of incoming light rays. As demonstrated by ray 160, incoming light having an angle of incidence (measured from vertical) greater than the critical TIR angle at the bottom surface of optical element 110 will be reflected back into optical element 110 rather than being refracted through encapsulant 120. For encapsulant thicknesses that are substantially greater than the wavelength of light, this TIR cutoff serves to limit the potential acceptance angle which could otherwise be achieved. Rays reaching the glass/encapsulant interface that are at angles larger than the TIR limit will be rejected. Consequently, a portion of usable solar energy will not be converted to electrical energy by solar cell 130 due to the mismatch of refractive indices between optical element 110 and encapsulant 120.

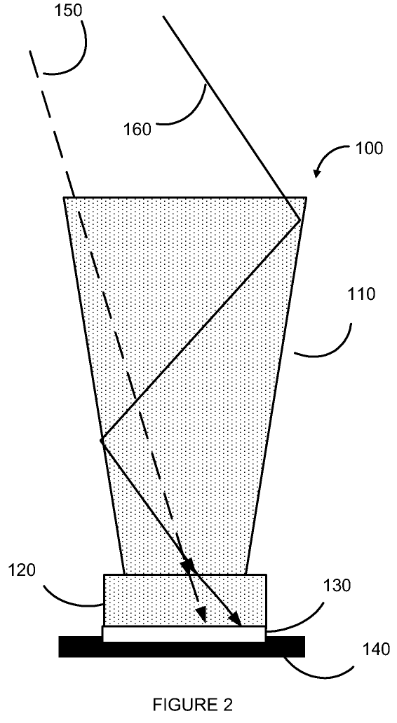

In contrast to FIG. 1, FIG. 2 depicts a cross sectional view of an ideal optical system 100. In FIG. 2, the refractive indices of optical element 110 and encapsulant 120 are matched, as represented by the identical shading of the two components. For example, optical element 110 may be silicone or any optically transparent material, and encapsulant 120 may be silicone or other polymers whose index of refraction matches that of the optical element 110. Because the refraction indices of optical element 110 and encapsulant 120 match, ray 160 is transmitted through encapsulant 120 rather than being completely reflected as in FIG. 1. Solar radiation incident on the optical element 110 at a wide range of angles may be directed to the solar cell 130.

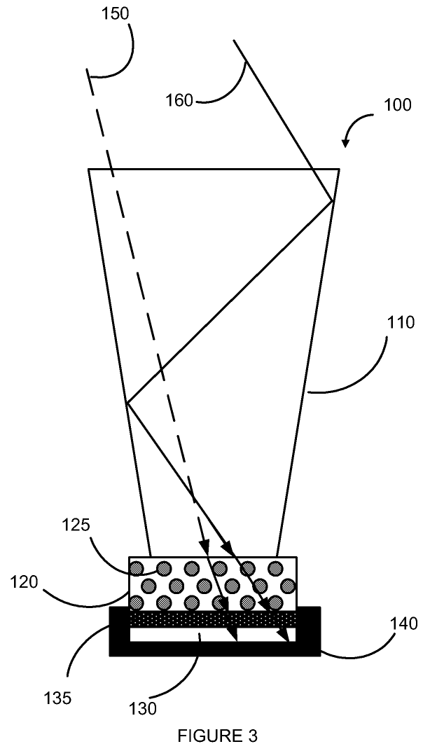

Because limited material choices exist in the industry to address the issues described in relation to FIG. 1, and because new materials to approach the ideal situation of FIG. 2 are not readily available, the present invention beneficially modifies encapsulant 120 to have a refractive index more closely matching that of the optical element 110. FIG. 3 depicts a cross sectional view of an exemplary optical system 100 of this invention which includes a filler material 125 in the encapsulant 120. In one embodiment the filler material 125 may be a material with a higher index of refraction than the encapsulant 120. The combined filler/encapsulant system may have a combined index of refraction which reduces the difference or substantially matches that of an optical element 110 or any optical device. In one embodiment, the filler material may be any dielectric material such as oxides (e.g., silica, zirconia, tantala or titania), nitrides (e.g., silicon nitride, alumina nitride), carbides (e.g., silicon carbide, diamond), or silicates (e.g., zircon) which when combined with the encapsulant material modifies the index of refraction of the system. In one embodiment the choice and amount of filler material may modify the refractive index of an encapsulant to within 5% of the refractive index of an optical element. In another embodiment the choice and amount of filler material may modify the refractive index of an encapsulant to within 1% of the refractive index of an optical element. In a particular embodiment, the filler material may TiO₂ spheres which have an index of refraction of 2.25.

In one aspect of designing a combined filler/encapsulant, or effective medium, with the desired performance characteristics, the particle size of filler material 125 may be considered. The particle size of filler material 125 may be chosen to be smaller than the shortest wavelength of light converted by the solar cell in a CPV system in order to reduce significant transmission loss due to Rayleigh scatter. In one embodiment, the filler material may be titania (e.g., TiO₂) spheres with a particle size of about 100-300 nm. In an exemplary embodiment, titanium dioxide TiO₂ spheres of 200 nm in diameter in a host encapsulant with a refractive index of 1.4 (e.g,. silicone) is estimated to result in a scatter of less than 1.4% for 400 nm light. In another embodiment of the invention, the filler material may be coated with an insulating material, (e.g., SiO₂) to prevent potential electrical transfer via the filler particles.

In another aspect of modifying the encapsulant 120, the volume fraction of filler material 125 may be chosen based on the desired change in encapsulant refractive index, as well as the refractive indices of the cured encapsulant and the filler material. If the particle size of filler material 125 is substantially sub-wavelength, the effective medium index can be computed for any index of refraction desired according to the following formula, for which n is the number of dimensions, “σ” stands for the dielectric constant (refractive index squared for optical frequencies), the “i” subscript is the filler material, and the “e” subscript is the effective medium formed of the mixture of filler and base material.

$${\sum }_{i} {δ}_{i} \frac{{σ}_{i} - {σ}_{e}}{{σ}_{i} + ( n - 1 ) {σ}_{e}} = 0$$

In one embodiment of the present invention, the volume of titania (e.g. TiO₂) filler material 125 in a silicone encapsulant 125 may be 10-20% to achieve an effective medium index of approximately 1.52. In a particular embodiment the volume of titania filler material in a silicone encapsulant may be 16%.

Filler material 125 may be added as a suspension to the encapsulant 120 and dispensed in colloidal suspension or by any other method known in the art for mixing and applying an encapsulant. The combined filler/encapsulant material may be applied to a surface of the optical element 110 in the colloidal suspension, subsequently cured and then disposed on a surface of the solar cell 130. In one embodiment a portion filler/encapsulant material may be cured on a surface of the optical element 110 and placed onto an uncured portion of filler/encapsulant material disposed on the surface of the solar cell 130. After the curing of both portions of the filler/encapsulant material, a solid optical flow path for incoming radiation with a matched index of refraction may be formed between the optical element 110 and the solar cell 130.

FIG. 3 shows a further optional feature of the present invention. An anti-reflective (AR) layer 135 may be disposed on the surface of the solar cell 130. The anti-reflective layer 135 may increase the amount of incident light that reaches the solar cell 130 by reducing Fresnel reflections between the solar cell 130 and encapsulating material 120. The solar cell 130 and AR layer 135 may be incorporated into a leadframe package 140. In another embodiment (not shown), a passivation layer may be disposed between the AR layer 135 and the solar cell 130 which may provide environmental protection for the solar cell. The material composition of the AR and passivation layers may also be optimized for effective refractive indices in order to maximize the angle at which solar radiation may reach the solar cell 130.

In a yet another embodiment of the present invention, the acceptance angle of an optical system may be improved by using a higher index material for both the encapsulant and the optical element, which may referred to more generally as the immersion material. The maximum possible light concentration in a CPV system for a given acceptance angle depends on the index of refraction of the immersion material. If the index of the immersing medium increases, the potential acceptance angle increases. The formula relating acceptance angle θ_{accept}, immersing index n, and geometric concentration C of an optical device (e.g. non-imaging concentrator) is shown below.

$${θ}_{accept} = \frac{arcsin ( ( n * sin ( {θ}_{cell} ) )}{\sqrt{[ C ]}}$$

In one embodiment of the invention, the acceptance angle of a CPV system may be raised by starting with a high refractive index glass (e.g. 1.8) or other material and coupling that with a filler/encapsulant system that would match this index of refraction. For instance, an encapsulant of silicone mixed with a 50% volume fill of titania (e.g. TiO₂) spheres may provide a refractive index substantially matching 1.8. For a geometric concentration of 850, this could increase the acceptance angle to 3.54 degrees from the 3.00 degrees potential associated with index 1.52.

### ADDITIONAL EXAMPLES

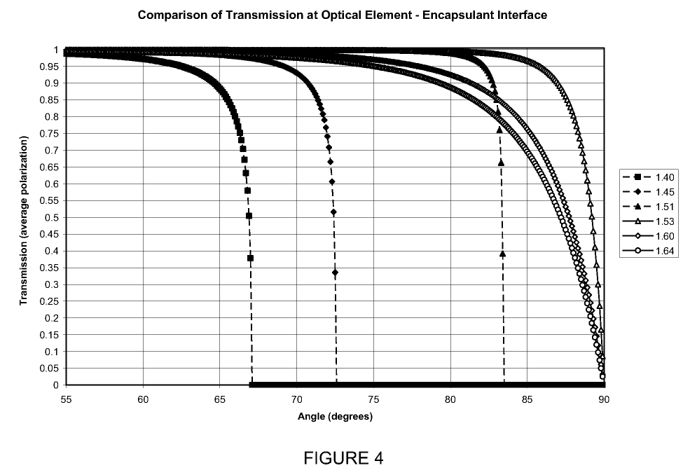

The simulation shown in the graph of FIG. 4 depicts the calculated transmission of light at the interface between an optical element and a series of encapsulants with varying indices of refraction. The transmission is calculated as a function of incidence angle of incoming light. For all cases, the index of refraction of the optical element is 1.52. The scenarios are depicted by curves that are shown in FIG. 4. In can be seen from curves corresponding to indices of refraction 1.40 (--▪--), 1.45 (--♦--), and 1.51 (--▴--) that as the index of refraction of the encapsulant approaches that of the optical element, the transmission of light increases dramatically at larger angles of incidence. When the index of refraction of the encapsulant is 1.51, the transmission of light is greater than 90% for light approaching at 83°. This represents an improvement of over 15° from light approaching an interface with an encapsulant that has an index of refraction of 1.40. It can also be seen that an encapsulant with an index of refraction just above (1.53 -□-) that of the optical element shows the best performance as 90% transmission levels may be achieved for incoming light above 86°. Curves representing encapsulants with higher indices of refraction 1.60 (-⋄-), and 1.64 (-∘-) which demonstrate that encapsulants exceeding the index of refraction of the optical element may result in a decrease in acceptance angle are also shown. An encapsulant with an index of refraction that matches that of the optical element would provide ideal transmission at all angles of incidence.

Taken together, the curves demonstrate that the impact of total internal reflection (TIR) and Fresnel reflectivity may be reduced when the encapsulant index is adjusted to match that of the optical device, as was described in relation to FIG. 3.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed:

1. An apparatus comprising:
an optical element having a first refractive index;
a solar cell, wherein the solar cell converts light associated with a range of wavelengths to electrical energy, the range having a minimum wavelength of light;
an encapsulant having a second refractive index, wherein the encapsulant is disposed between the optical element and the solar cell; and
wherein the second refractive index of the encapsulant is modified to approach the value of the first refractive index.

2. The apparatus of claim 1, wherein the optical element is a non-imaging concentrator.

3. The apparatus of claim 1, wherein the second refractive index is modified to match the first refractive index.

4. The apparatus of claim 1, wherein the encapsulant comprises silicone and a filler material.

5. The apparatus of claim 4, wherein the filler material comprises titania.

6. The apparatus of claim 4, wherein the filler material comprises particulates smaller than the minimum wavelength.

7. The apparatus of claim 4, wherein the filler material comprises particulates smaller than 300 nm in diameter.

8. The apparatus of claim 4, wherein the filler material comprises 10-20% volume of the encapsulant.

9. The apparatus of claim 1, further comprising an anti-reflective layer between the optical element and the solar cell.

10. A method of increasing the acceptance angle of an optical system, wherein the optical system comprises an optical element having a first refractive index and an encapsulant having a second refractive index, the method comprising:
modifying the encapsulant to cause the second refractive index to approach the value of the first refractive index;
applying the encapsulant to the optical element; and
coupling a solar cell to the encapsulant, wherein the solar cell converts light associated with a range of wavelengths to electrical energy, the range having a minimum wavelength of light.

11. The method of claim 10, wherein the step of modifying comprises adding a filler material to the encapsulant.

12. The method of claim 11, wherein the filler material is titanium dioxide.

13. The method of claim 11, wherein the filler material is associated with an index of refraction greater than 1.4.

14. The method of claim 11, wherein the filler material comprises particulates smaller than the minimum wavelength.

15. The method of claim 11, wherein the filler material comprises particulates smaller than 300 nm in diameter.

16. The method of claim 11, wherein the filler material is 10-20% volume of the encapsulant.

17. The method of claim 10, further comprising the step of applying an anti-reflective layer to the solar cell.
